(19) United States
(12) Patent Application Publication
(10) Pub. No.: US 2017/0318708 A1
(43) Pub. Date: Nov. 2, 2017

(54) SYSTEMS AND METHODS FOR CONTROLLING AIR MOVER SPEED DURING BOOT OF INFORMATION HANDLING SYSTEM

(71) Applicant: Dell Products L.P., Round Rock, TX (US)

(72) Inventors: Hasnain SHABBIR, Round Rock, TX (US); Dominick A. LOVICOTT, Round Rock, TX (US); Dinesh Kunnathur RAGUPATHI, Round Rock, TX (US); Daniel WHITTINGTON, Austin, TX (US)

(73) Assignee: Dell Products L.P., Round Rock, TX (US)

(21) Appl. No.: 15/143,175

(22) Filed: Apr. 29, 2016

(51) Int. Cl. H05K 7/20; G05B 15/02

(52) U.S. Cl. CPC H05K 7/20836; G05B 15/02

(57) ABSTRACT

In accordance with embodiments of the present disclosure, a system may include an air mover control system configured to, during a boot session of an information handling system, determine an initial air mover speed to be applied to an air mover during a second boot session based on a hardware configuration of the information handling system, and store a variable indicative of the initial air mover speed, such that the air mover control system may apply the initial air mover speed during boot of the second boot session.

### TECHNICAL FIELD

The present disclosure relates in general to information handling systems, and more particularly to controlling speed of an air mover during boot of an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Temperature control in an information handling system with air movers often involves use of open-loop and/or closed-loop feedback systems to control speed of an air mover and thus, the amount of air driven by air movers. Oftentimes, during boot of an information handling system, default or non-optimum air mover control is applied, as during boot an information handling system may not be cognizant of a system configuration/hardware inventory for the information handling system, and thus a “worst case” or other default air mover speed may be applied. In some embodiments, such default speed may be well in excess of what is needed for adequate cooling during boot, thus potentially wasting power efficiency as well as generating unnecessary acoustical noise. In other embodiments, such default speed may be insufficient to provide adequate cooling during booting, which may be the case where legacy cooling approaches do not account for upgraded components (e.g., unmatched peripheral cards) that may require more cooling than the default legacy approach.

### SUMMARY

In accordance with the teachings of the present disclosure, the disadvantages and problems associated with controlling an air mover speed during boot of an information handling system may be substantially reduced or eliminated.

In accordance with embodiments of the present disclosure, a system may include an air mover control system configured to, during a boot session of an information handling system, determine an initial air mover speed to be applied to an air mover during a second boot session based on a hardware configuration of the information handling system, and store a variable indicative of the initial air mover speed, such that the air mover control system may apply the initial air mover speed during boot of the second boot session.

In accordance with these and other embodiments of the present disclosure, an information handling system may include a processor and a management controller communicatively coupled to the processor and configured to, during a boot session of an information handling system, determine an initial air mover speed to be applied to an air mover during a second boot session based on a hardware configuration of the information handling system, and store a variable indicative of the initial air mover speed, such that the management controller may apply the initial air mover speed during boot of the second boot session.

In accordance with these and other embodiments of the present disclosure, a method may include during a boot session of an information handling system, determining an initial air mover speed to be applied to an air mover during a second boot session based on a hardware configuration of the information handling system, and storing a variable indicative of the initial air mover speed, such that the initial air mover speed is applied during boot of the second boot session.

In accordance with these and other embodiments of the present disclosure, an article of manufacture may include a non-transitory computer-readable medium and computer-executable instructions carried on the computer-readable medium, the instructions readable by a processor, the instructions, when read and executed, for causing the processor to: (i) during a boot session of an information handling system, determine an initial air mover speed to be applied to an air mover during a second boot session based on a hardware configuration of the information handling system; and (ii) store a variable indicative of the initial air mover speed, such that the initial air mover speed is applied during boot of the second boot session.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure; and

FIG. 2 illustrates a flow chart of an example method for controlling air mover speed during boot of an information handling system, in accordance with embodiments of the present disclosure.

### DETAILED DESCRIPTION

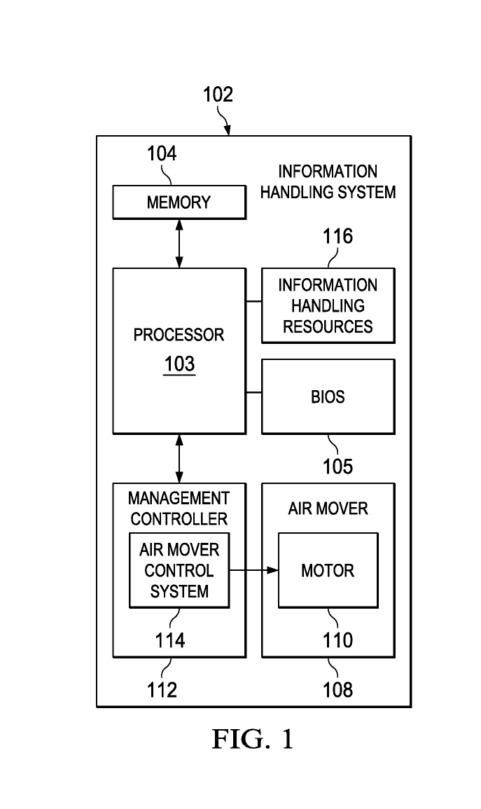

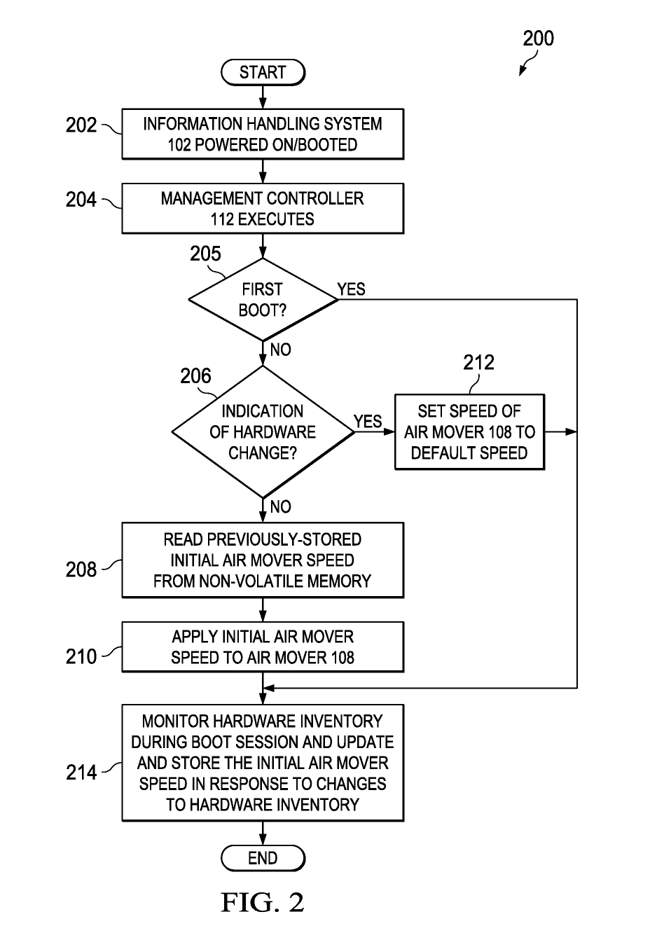

Preferred embodiments and their advantages are best understood by reference to FIGS. 1 and 2, wherein like numbers are used to indicate like and corresponding parts. For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104, a basic input/output system (BIOS) 105, an air mover 108, and a management controller 112.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

A BIOS 105 may include any system, device, or apparatus configured to identify, test, and/or initialize information handling resources of information handling system 102, and/or initialize interoperation of information handling system 102 with other information handling systems. “BIOS” may broadly refer to any system, device, or apparatus configured to perform such functionality, including without limitation, a Unified Extensible Firmware Interface (UEFI). In some embodiments, BIOS 105 may be implemented as a program of instructions that may be read by and executed on processor 103 to carry out the functionality of BIOS 105. In these and other embodiments, BIOS 105 may comprise boot firmware configured to be the first code executed by processor 103 when information handling system 102 is booted and/or powered on. As part of its initialization functionality, code for BIOS 105 may be configured to set components of information handling system 102 into a known state, so that one or more applications (e.g., an operating system or other application programs) stored on compatible media (e.g., disk drives) may be executed by processor 103 and given control of information handling system 102. In some embodiments, BIOS 105 may also be configured to store and/or report configuration information regarding a hardware configuration (e.g., population of various information handling resources) of information handling system 102.

Air mover 108 may include any mechanical or electro-mechanical system, apparatus, or device operable to move air and/or other gases in order to cool information handling resources of information handling system 102. In some embodiments, air mover 108 may comprise a fan (e.g., a rotating arrangement of vanes or blades which act on the air). In other embodiments, air mover 108 may comprise a blower (e.g., centrifugal fan that employs rotating impellers to accelerate air received at its intake and change the direction of the airflow). In these and other embodiments, rotating and other moving components of air mover 108 may be driven by a motor 110. The rotational speed of motor 110 may be controlled by an air mover control signal (e.g., a pulse-width modulation signal) communicated from air mover control system 114 of management controller 112. In operation, air mover 108 may cool information handling resources of information handling system 102 by drawing cool air into an enclosure housing the information handling resources from outside the chassis, expel warm air from inside the enclosure to the outside of such enclosure, and/or move air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include an air mover control system 114. Air mover control system 114 may include any system, device, or apparatus configured to receive information regarding a hardware configuration of information handling system 102, and based on such information, calculate an air mover driving signal (e.g., a pulse-width modulation signal) to maintain an appropriate level of cooling, increase cooling, or decrease cooling, as appropriate, and communicate such air mover driving signal to air mover 108. In some embodiments, air mover control system 114 may include a program of instructions (e.g., software, firmware) configured to, when executed by a processor or controller integral to management controller 112, carry out the functionality of air mover control system 114. In operation, air mover control system 114 may control air mover speed of air mover 108 (e.g., motor 110) during boot of information handling system 102, in order to optimize speed of air mover 108 based on a previously-known and stored hardware configuration present during a previous boot session, as described in greater detail below with respect to FIG. 2.

In addition to processor 103, memory 104, BIOS 105, air mover 108, and management controller 112, information handling system 102 may include one or more other information handling resources 116 which make up a hardware inventory or configuration of information handling system 102. In addition, for the sake of clarity and exposition of the present disclosure, FIG. 1 depicts only one air mover 108. In embodiments of the present disclosure, information handling system 102 may include any number of air movers 108.

FIG. 2 illustrates a flow chart of an example method 200 for controlling air mover speed during boot of an information handling system, in accordance with embodiments of the present disclosure. According to one embodiment, method 200 may begin at step 202. As noted above, teachings of the present disclosure may be implemented in a variety of configurations of information handling system 102 and/or air mover control system 114. As such, the preferred initialization point for method 200 and the order of the steps comprising method 200 may depend on the implementation chosen.

At step 202, information handling system 102 may be powered on or otherwise booted (e.g., by a user powering on or booting information handling system 102, or information handling system 102 being booted by a technician at a factory at which information handling system 102 is manufactured). Such booting of information handling system 102 may cause processor 103 and management controller 112 to also boot.

At step 204, management controller 112 may initialize and boot (e.g., execute a bootloader application such as U-boot, or an operating system or firmware of management controller 112, either or both of which may embody some or all of air mover control system 114). At step 205, management controller 112 may determine whether the present boot is the first boot of information handling system 102. If the present boot is the first boot, method 200 may proceed to step 214. Otherwise, method 200 may proceed to step 206.

At step 206, management controller 112 may determine whether an indication of a hardware modification has occurred since a previous boot session or power cycle. For example, such indication of a hardware modification may comprise a chassis intrusion of information handling system 102 since a previous boot session or power cycle. A chassis intrusion may indicate that a hardware inventory has occurred since the previous boot session, while absence of a chassis intrusion may indicate that the hardware inventory is unchanged. In some embodiments, a flag or other variable may indicate whether chassis intrusion has occurred (e.g., by means of a battery-powered circuit configured to assert or de-assert such flag or variable in a memory or other computer-readable medium in response to a sensor detecting a chassis intrusion). In some of such embodiments, such flag or other variable may be set to indicate chassis intrusion prior to the first boot or power on of information handling system 102 so that default or non-optimum speed of air mover 108 is applied during such initial boot or power on, as hardware configuration of information handling system 102 may not be known by air mover control system 114 prior to such power on. Although the foregoing contemplates a “active” chassis intrusion detection as an indication of hardware modification, passive chassis intrusion may also be employed in addition to or in lieu of chassis intrusion detection. Although the foregoing contemplates a chassis intrusion as an indication of hardware modification, other indications of hardware change (e.g., bezel removal detection) may also be employed in addition to or in lieu of chassis intrusion detection. If an indication of hardware modification has occurred, method 200 may proceed to step 212. Otherwise, an indication of hardware modification has not occurred, method 200 may proceed to step 208.

At step 208, in response to an absence of an indication of a hardware modification since the most recent previous boot session, air mover control system 114 may read a previously-stored initial air mover speed from non-volatile memory (e.g., a non-volatile memory integral to or otherwise accessible to air mover control system 114). Such previously-stored initial air mover speed may have been stored by air mover control system 114 during a previous boot session, based on the hardware inventory of information handling system 102 during such boot session. At step 210, air mover control system 114 may apply such initial air mover speed to air mover 108. After completion of step 210, method 200 may proceed to step 214.

At step 212, in response to an indication of a hardware modification since the most recent previous boot session, air mover control system 114 may (during bootloader execution) set a speed of air mover 108 to a default speed (e.g., 50% of full-range speed). In some embodiments, such default speed may be based on a user-defined default speed (e.g., instead of a factory-defined default speed) which may take into account user knowledge of the environment in which information handling system 102 may be used (e.g., a priori user knowledge that the user's data center environment has a higher than normal ambient temperature).

At step 214, air mover control system 114 may monitor hardware inventory during the boot session (e.g., which may change due to plug-and-play of devices), update the speed of air mover 108 responsive to such changes (and in closed-loop control systems, based on measured temperatures), and may update and store the initial air mover speed in response to changes to hardware inventory, so that a suitable initial air mover speed is applied during a subsequent boot session. Such initial fan speed may be determined in any suitable manner, including setting the initial fan speed based on any open loop and/or closed loop control parameters during a boot session (e.g., storing a maximum steady state air mover speed achieved during the boot session, which may accurately represent operating conditions associated with information handling system 102). After completion of step 214, method 200 may end.

Although FIG. 2 discloses a particular number of steps to be taken with respect to method 200, method 200 may be executed with greater or lesser steps than those depicted in FIG. 2. In addition, although FIG. 2 discloses a certain order of steps to be taken with respect to method 200, the steps comprising method 200 may be completed in any suitable order.

Method 200 may be implemented using information handling system 102, air mover control system 114, or any other system operable to implement method 200. In certain embodiments, method 200 may be implemented partially or fully in software and/or firmware embodied in computer-readable media.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

What is claimed is:

1. A system comprising an air mover control system configured to:
during a boot session of an information handling system, determine an initial air mover speed to be applied to an air mover during a second boot session based on a hardware configuration of the information handling system; and
store a variable indicative of the initial air mover speed, such that the air mover control system may apply the initial air mover speed during boot of the second boot session.

2. The system of claim 1, wherein the air mover control system is further configured to, during boot of the boot session:
determine if an event has occurred indicative of a modification to the hardware configuration; and
responsive to determining the event has occurred, apply the initial air mover speed as stored during a third boot session previous to the boot session.

3. The system of claim 2, wherein the air mover control system is further configured to, during boot of the boot session and responsive to determining the event has not occurred, apply at least one of a default air mover speed and an air mover speed based on a boot code generated by a basic input/output system of the information handling system.

4. The system of claim 2, wherein the event comprises an intrusion into a chassis of the information handling system.

5. The system of claim 1, wherein the air mover control system is further configured to, during the boot session:
monitor modifications to the hardware configuration; and
update the initial air mover speed based on modifications to the hardware configuration.

6. An information handling system comprising:
a processor; and
a management controller communicatively coupled to the processor and configured to:
during a boot session of an information handling system, determine an initial air mover speed to be applied to an air mover during a second boot session based on a hardware configuration of the information handling system; and
store a variable indicative of the initial air mover speed, such that the management controller may apply the initial air mover speed during boot of the second boot session.

7. The information handling system of claim 6, wherein the management controller is further configured to, during boot of the boot session:
determine if an event has occurred indicative of a modification to the hardware configuration; and
responsive to determining the event has occurred, apply the initial air mover speed as stored during a third boot session previous to the boot session.

8. The information handling system of claim 7, wherein the management controller is further configured to, during boot of the boot session and responsive to determining the event has not occurred, apply at least one of a default air mover speed and an air mover speed based on a boot code generated by a basic input/output system of the information handling system.

9. The information handling system of claim 7, wherein the event comprises an intrusion into a chassis of the information handling system.

10. The information handling system of claim 6, wherein the management controller is further configured to, during the boot session:
monitor modifications to the hardware configuration; and
update the initial air mover speed based on modifications to the hardware configuration.

11. A method comprising:
during a boot session of an information handling system, determining an initial air mover speed to be applied to an air mover during a second boot session based on a hardware configuration of the information handling system; and
storing a variable indicative of the initial air mover speed, such that the initial air mover speed is applied during boot of the second boot session.

12. The method of claim 11, further comprising, during boot of the boot session:
determining if an event has occurred indicative of a modification to the hardware configuration; and
responsive to determining the event has occurred, applying the initial air mover speed as stored during a third boot session previous to the boot session.

13. The method of claim 12, further comprising, during boot of the boot session and responsive to determining the event has not occurred, applying at least one of a default air mover speed and an air mover speed based on a boot code generated by a basic input/output system of the information handling system.

14. The method of claim 12, wherein the event comprises an intrusion into a chassis of the information handling system.

15. The method of claim 11, further comprising, during the boot session:
monitoring modifications to the hardware configuration; and
updating the initial air mover speed based on modifications to the hardware configuration.

16. An article of manufacture comprising:
a non-transitory computer-readable medium; and
computer-executable instructions carried on the computer-readable medium, the instructions readable by a processor, the instructions, when read and executed, for causing the processor to:
during a boot session of an information handling system, determine an initial air mover speed to be applied to an air mover during a second boot session based on a hardware configuration of the information handling system; and
store a variable indicative of the initial air mover speed, such that the initial air mover speed is applied during boot of the second boot session.

17. The article of claim 16, the instructions for further causing the processor to, during boot of the boot session:
determine if an event has occurred indicative of a modification to the hardware configuration; and
responsive to determining the event has occurred, apply the initial air mover speed as stored during a third boot session previous to the boot session.

18. The article of claim 17, the instructions for further causing the processor to, during boot of the boot session and responsive to determining the event has not occurred, apply at least one of a default air mover speed and an air mover speed based on a boot code generated by a basic input/output system of the information handling system.

19. The article of claim 17, wherein the event comprises an intrusion into a chassis of the information handling system.

20. The article of claim 16, the instructions for further causing the processor to, during the boot session:
monitor modifications to the hardware configuration; and
update the initial air mover speed based on modifications to the hardware configuration.
